(19) United States
(12) Patent Application Publication
(10) Pub. No.: US 2007/0290607 A1
(43) Pub. Date: Dec. 20, 2007

(54) ORGANIC ELECTROLUMINESCENT DISPLAY DEVICE

(76) Inventors: Naotada OKADA, Yokohama-shi (JP); Junichi Tonotani, Yokohama-shi (JP); Satoshi Okutani, Tokyo (JP); Hiroshi Sano, Tokyo (JP); Tsuyoshi Uemura, Tokyo (JP); Muneharu Akiyoshi, Tokyo (JP); Hirofumi Kubota, Tokyo (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/693,399

(22) Filed: Mar. 29, 2007

Related U.S. Application Data
(63) Continuation of application No. PCT/JP2005/017840, filed on Sep. 28, 2005.

(30) Foreign Application Priority Data
Sep. 30, 2004 (JP) 2004-288412
Sep. 30, 2004 (JP) 2004-288413
Sep. 30, 2004 (JP) 2004-288414

(51) Int. Cl. H01J 1/70

(52) U.S. Cl. 313/504

(57) ABSTRACT

Disclosed is an organic electroluminescent display device, comprising a light-transmitting insulating layer, an organic electroluminescent element including a back side electrode arranged on the back side of the light transmitting insulating layer, a light-transmitting front side electrode interposed between the light-transmitting insulating layer and the back side electrode, and an organic material layer interposed between the front side electrode and the back side electrode and containing a light-emitting layer, and a three-dimensional diffraction element of a two-layer structure arranged on the optical path guiding the light emitted from the light-emitting layer included in the organic material layer to reach the light-transmitting insulating layer, wherein the three-dimensional diffraction element has a cross-sectional structure of a specified dielectric modulation.

### CROSS-REFERENCE TO RELATED APPLICATIONS

This is a Continuation Application of PCT Application No. PCT/JP2005/017840, filed Sep. 28, 2005, which was published under PCT Article 21(2) in Japanese.

This application is based upon and claims the benefit of priority from prior Japanese Patent Applications No. 2004-288412, filed Sep. 30, 2004; No. 2004-288413, filed Sep. 30, 2004; and No. 2004-288414; filed Sep. 30, 2004, the entire contents of all of which are incorporated herein by reference.

### BACKGROUND OF THE INVENTION

1. Field of the Invention

The present invention relates to an organic electroluminescent (organic EL) display device.

2. Description of the Related Art

An organic EL display device, which is a self-emission display device, is featured in that the viewing angle is wide and that the response speed is high. Also, since the back light is not required, the display device can be made thin and light in weight. Such being the situation, the organic EL display device attracts attentions in recent years in place of a liquid crystal display device as a display device of, for example, a portable telephone.

The organic EL element constituting a main part of the organic EL display device is a charge injection type self-emission element comprising a front side electrode that transmits light, a back side electrode arranged to face the front side electrode and formed of a light reflective or a light-transmitting material and an organic material layer interposed between the front side electrode and the back side electrode and including a light-emitting layer. If an electric current is allowed to flow through the organic material layer, the organic EL element is caused to emit light. For allowing the organic EL display device to perform the display, it is necessary for the light generated from the light-emitting layer to be emitted to the outside through the front side electrode. The light rays running within the element toward the front side include light rays running toward the broad angle side. It should be noted in this connection that the light rays running toward the broad angle side is subjected to the total internal reflection at the interface between the front side electrode and the layer formed below the front side electrode. As a result, it is impossible to extract much of the light emitted from the organic material layer to the outside of the organic EL element, leading to the problem that the light-extraction efficiency of the organic EL element is low.

Such being the situation, Japanese Patent No. 2991183 teaches that among the light rays running within the element toward the front side, the light rays running toward the broad angle side is diffracted by utilizing a diffraction element or a zone plate so as to permit the diffracted light rays to pass through the interface of the front side electrode. This technology makes it possible to improve the light-extraction efficiency of the organic EL element.

In Japanese Patent No. 2991183 quoted above, however, the pattern constituting the diffraction element or the zone plate has a directional property and, thus, the directivity of the light that is extracted differs depending on the direction. It follows that the image display is made inappropriate in some of the organic EL display device. Also, it is necessary for the fine shape of the diffraction element or the zone plate to be formed by, for example, the lithography, leading to high manufacturing cost.

### BRIEF SUMMARY OF THE INVENTION

According to a first aspect of the present invention, there is provided an organic electroluminescent display device, comprising:

a light-transmitting insulating layer;

an organic electroluminescent element including a back side electrode arranged on the back side of the light transmitting insulating layer, a light-transmitting front side electrode interposed between the light-transmitting insulating layer and the back side electrode, and an organic material layer interposed between the front side electrode and the back side electrode and containing a light-emitting layer; and

a three-dimensional diffraction element of a two-layer structure arranged on the optical path guiding the light emitted from the light-emitting layer included in the organic material layer to reach the light-transmitting insulating layer;

wherein the three-dimensional diffraction element has a cross-sectional structure of a dielectric modulation represented by formula (1) given below and satisfies the relationship of Δ∈1>Δ∈q satisfied, where Δ∈1 denotes the amplitude in the case where q in formula (1) is equal to 1 (q=1), and Δ∈q denotes the amplitude of another degree in the case where q in formula (1) is larger than 1 (q>1):

$$Δɛ ( z ) = {\sum }_{q} Δ {ɛ}_{q} cos ( qKz ) \qquad ( 1 )$$

where

Δ∈(z) denotes the change in the dielectric constant in a position z;

Δ∈q denotes the amplitude of the term of the q degree;

K is equal to 2π/Λ (where Λ denotes the period); and

z denotes the position in the horizontal direction.

According to a second aspect of the present invention, there is provided is an organic electroluminescent display device, comprising:

a light-transmitting insulating layer; and

an organic electroluminescent element including a back side electrode mounted to the back side of the light-transmitting insulating layer, a light-transmitting front side electrode interposed between the light-transmitting insulating layer and the back side electrode, and an organic material layer interposed between the front side electrode and the back side electrode and including a light-emitting layer;

wherein the organic electroluminescent element is bent at a desired period to form a waved configuration.

According to a third aspect of the present invention, there is provided an organic electroluminescent display device, comprising:

a light-transmitting insulating layer;

an organic EL element including a back side electrode mounted to the back side of the light-transmitting insulating layer, a light-transmitting front side electrode interposed between the light-transmitting insulating layer and the back side electrode, and an organic material layer interposed between the front side electrode and the back side electrode and including a light-emitting layer; and

a fine particle dispersion layer arranged on the optical path guiding the light emitted from the light-emitting layer included in the organic material layer to reach the light-transmitting insulating layer;

wherein the fine particle dispersion layer comprises a base material and a large number of fine particles dispersed in the base material and differing from the base material in the refractive index.

According to a fourth aspect of the present invention, there is provided an organic electroluminescent display device, comprising:

an organic electroluminescent element including a light-transmitting back side electrode, a light-transmitting front side electrode arranged to face the back side electrode, and an organic material layer interposed between the back side electrode and the front side electrode and including a light-emitting layer;

a reflective layer arranged to face the front side electrode; and

a light-transmitting flattening layer interposed between the reflective layer and the organic electroluminescent element;

wherein those surfaces of the reflective layer which are positioned to face the organic EL element are arranged at a prescribed pitch, each of the reflective layer and the organic electroluminescent element includes a plurality of convex portions and concave portions each having a cross section that is tapered forward, each of the height of the convex portion and the depth of the concave portion being not smaller than 0.5 μm, the pitch being not smaller than 3 μm, and, when a cross section of the reflective layer is viewed, those surfaces of the reflective layer which are positioned to face the organic electroluminescent element depicts a substantially sinusoidal waveform.

According to a fifth aspect of the present invention, there is provided an organic electroluminescent display device, comprising:

an organic electroluminescent element including a light-transmitting back side electrode, a light-transmitting front side electrode positioned to face the back side electrode and an organic material layer interposed between the back side electrode and the front side electrode and including a light-emitting layer;

a reflective layer positioned to face the front side electrode; and

a light-transmitting flattening layer interposed between the reflective layer and the organic electroluminescent layer;

wherein the those surfaces of the reflective layer which are positioned to face the organic electroluminescent layer include a plurality of convex portions or concave portions each having a cross section that is tapered forward.

### BRIEF DESCRIPTION OF THE SEVERAL VIEWS OF THE DRAWING

FIG. 1 is a cross-sectional view schematically showing the construction of the organic electroluminescent (EL) display device according to a first embodiment;

FIG. 2 is a plan view showing the construction of a three-dimensional diffraction element shown in FIG. 1;

FIG. 3 is a cross-sectional view along the line III-III shown in FIG. 2;

FIG. 4 is a cross-sectional view schematically showing the construction of an organic EL display device according to a second embodiment;

FIG. 5 is a cross-sectional view showing the gist portion of the organic EL display device shown in FIG. 4;

FIG. 6 is a cross-sectional view schematically showing the construction of an organic EL display device according to a third embodiment;

FIG. 7 is a graph showing the relationship between the diameter of the fine particles dispersed in a fine particle dispersion layer and the light-extraction efficiency in respect of the organic EL display device shown in FIG. 6;

FIG. 8 is a cross-sectional view schematically showing the construction of an organic EL display device according to a fourth embodiment;

FIG. 9 is a cross-sectional view showing in a magnified fashion a pat of the organic EL display device shown in FIG. 8; and

FIGS. 10, 11, 12 and 13 are a cross-sectional view schematically exemplifying the method that can be applied to the manufacture of the organic EL display device shown in FIG. 8.

### DETAILED DESCRIPTION OF THE INVENTION

The organic EL display devices according to some embodiments of the present invention will now be described in detail with reference to the accompanying drawings.

### First Embodiment

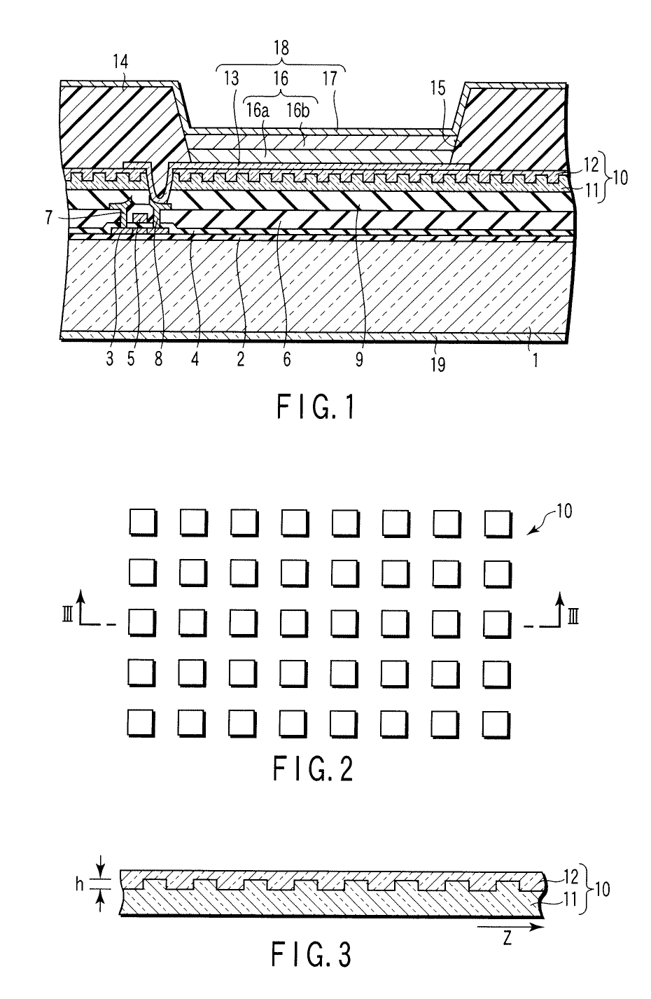

FIG. 1 is a cross-sectional view schematically showing the construction of a lower surface light emission type organic electroluminescent (EL) display device employing the active matrix type driving system according to a first embodiment, FIG. 2 is a plan view showing the construction of a three-dimensional diffraction element included in the organic EL display device shown in FIG. 1, and FIG. 3 is a cross-sectional view along the line III-III shown in FIG. 2.

Incidentally, the organic EL display device is depicted in FIG. 1 to permit the display surface i.e., the front side, of the organic EL display device to face downward and to permit the back side of the display device to face upward.

A plurality of pixels are arranged to form a matrix on a light-transmitting insulating layer forming a transparent substrate 1 such as a glass substrate. Each pixel includes, for example, an element control circuit, an output switch, an organic EL element described herein later and a pixel switch, which are connected in series between a pair of power source terminals. The element control circuit is connected to a video signal line via the pixel switch and serve to supply an electric current to the organic EL element via the output switch. The electric current noted above has a magnitude corresponding to the video signal supplied from a video signal driving circuit via the video signal line and the pixel switch. Also, the control terminal of the pixel switch is connected to a scanning signal line so as to permit the on/off operation of the pixel switch to be controlled by the scanning signal supplied from a scanning signal driving circuit via the scanning signal line. Further, the control terminal of the output switch is connected to the scanning signal line so as to permit the on/off operation of the output switch to be controlled by the scanning signal supplied from the scanning signal line driving circuit via the scanning signal line. Incidentally, it is also possible to employ other constructions in these pixels.

An undercoat layer 2 in which, for example, a SiNₓ layer and a SiOₓ layer are formed in the order mentioned, is formed on the substrate 1. Further, a semiconductor layer 3, a gate insulating film 4 and a gate electrode 5 are formed in the order mentioned on the undercoat layer 2 so as to form a top-gate-type thin-film transistor (TFT). The semiconductor layer 3 consists of poly-Si having, for example, a channel region, a source region and a drain region formed therein. The gate insulating film 4 is formed of, for example, tetraethyl ortho silicate (TEOS). Further, the gate electrode 5 is formed of, for example, MoW. In this example, the particular TFT is utilized in the pixel switch, the output switch, and the element control circuit. It should be noted that a scanning signal line (not shown) that is also formed in the process of forming the gate electrode 5 is formed on the gate insulating film 4.

An interlayer insulating film 6 consisting of SiOₓ formed by, for example, a plasma CVD method, is formed on the gate insulating film 4 including the gate electrode 5. Source/drain electrodes 7, 8, which are formed on the interlayer insulating layer 6, are connected, respectively, to the source region and the drain region of the TFT via contact holes formed through the interlayer insulating film 6. Each of the source/drain electrodes 7, 8 has a three layer structure of, for example, Mo/Al/Mo. Also, a video signal line (not shown) that can be formed in the process of forming the source/drain electrodes 7, 8 is formed on the interlayer insulating film 6. Further, a passivation film 9 consisting of, for example, SiNₓ is formed on the interlayer insulating film 6 including the source/drain electrodes 7, 8.

A three-dimensional diffraction element 10 used as a light-extraction means is formed on the passivation film 9. As shown in FIGS. 1, 2 and 3, the three-dimensional diffraction element 10 has a double layer structure consisting of a first layer 11 formed of a transparent inorganic material such as SiNₓ and a second layer 12 formed on the first layer 11 and differing from the first layer 11 in the material. To be more specific, the second layer 12 is formed of an organic insulating material such as resist or polyimide. The three-dimensional diffraction element 10 has a cross-sectional structure of the dielectric constant modulation (e.g., lattice shaped) represented by the Fourier series of formula (1) given below:

$$Δɛ ( z ) = {\sum }_{q} Δ {ɛ}_{q} cos ( qKz ) \qquad ( 1 )$$

where

Δ∈(z) denotes the change in the dielectric constant in the position z;

Δ∈q denotes the amplitude of the term of the q degree;

K is equal to 2π/Λ (where Λ denotes the period); and

z denotes the position in the horizontal direction.

In order to extract the light from, for example, the light-transmitting insulating layer (transparent substrate 1) in a manner to have a directivity, it is advantageous for the three-dimensional diffraction element to be shaped to permit the primary light alone to be extracted or to permit the primary light to be intensified. To be more specific, it is necessary to satisfy the condition of Δ∈1>Δ∈q where Δ∈1 denotes the amplitude in the case where q is equal to 1 (q=1) and Δ∈q denotes the amplitude of the other degree in the case where q is larger than 1 (q>1).

It is desirable for the three-dimensional diffraction element 10 to perform its function sufficiently for the confined light and not to perform its function for the light that is extracted. Concerning the efficiency for the light that is extracted, the periodic structure of the refractive index shown in FIG. 3 assumes the maximum depth (h) under the condition of h=λ/2(n1−n2), where λ denotes the wavelength of light, n1 denotes the refractive index of the first layer 11 and n2 denotes the refractive index of the second layer 12. The depth h is 125 nm under the conditions that n1=2.0, n2=1.5 and λ=500 nm. On the other hand, the oozing of the confined light is not larger than 100 nm in many cases. It follows that it is desirable for the depth h to be smaller than 125 nm (h<125 nm).

The through hole communicating with the drain electrode 8 extends through the passivation film 9 and the three-dimensional diffraction element 10. A plurality of light-transmitting front side electrodes 13 are arranged apart from each other on the three-dimensional diffraction element 10. In this example, the front side electrode 13 forms an anode and is formed of a transparent conductive oxide such as indium tin oxide (ITO). The front side electrode 13 is electrically connected to the drain electrode 8 via the through hole noted above.

A partition wall insulating layer 14 is formed on the three-dimensional diffraction element 10 including the front side electrode 13. A through hole 15 is formed in the partition wall insulating layer 14 in a manner to correspond to the front side electrode 13. The partition wall insulating layer 14 is formed of, for example, an organic insulating layer, which can be formed by using the photolithography technology.

An organic material layer 16 including a light-emitting layer 16a is formed on the front side electrode 13 exposed within the through hole 15 formed in the partition wall insulating layer 14. The light-emitting layer 16a is provided by a thin film containing a luminescent organic compound that emits red, green or blue light. It is possible for the organic material layer 16 to contain another layer in addition to the light-emitting layer 16a. For example, it is possible for the organic material layer 16 to further contain a buffer layer 16b serving to assist the hole injection from the front side electrode 13 into the light-emitting layer 16a. Also, it is possible for the organic material layer 16 to further include, for example, a hole transfer layer, a hole blocking layer, an electron transfer layer and an electron injection layer.

A reflective back side electrode 17 is formed to cover the partition wall insulating layer 14 and the organic material layer 16. In this example, the back side electrode 17 is used as a cathode that is consecutively formed as a common electrode of the pixels. The back side electrode 17 is electrically connected to an electrode wiring formed on the layer equal to the video signal line via a contact hole (not shown) extending through the passivation film 9, the three-dimensional diffraction element 10 and the partition wall insulating layer 14. These front side electrode 13, the organic material layer 16 and the back side electrode 17 collectively form an organic EL element 18.

In the self-emission display device in which pixels including self-emission elements and pixel switches arranged to correspond to the self-emission elements are arranged to form a matrix, a light-extraction means is arranged on the display side or the back side of the display device. Incidentally, the organic EL display device shown in FIG. 1 further includes in general a sealed substrate (not shown) arranged to face the back side electrode 17, and a sealed layer (not shown) arranged along the periphery of the sealed substrate facing the back side electrode 17. As a result, a hermetic space is formed between the back side electrode 17 and the sealed substrate. The particular hermetic space is filled with, for example, a rare gas such as an Ar gas or an inert gas such as a N₂ gas. In addition, the organic EL display device further comprises a light scattering layer 19 acting as a diffusion means. The light scattering layer 19 is arranged on the outside, i.e., the front side, of the transparent substrate 1.

As described above, according to the first embodiment, the three-dimensional diffraction element 10 having a specified cross-sectional structure of the dielectric constant modulation represented by formula (I) given previously is arranged on the optical path guiding the light emitted from the light-emitting layer 16a included in the organic material layer 16 to the light-transmitting insulating layer (e.g., the transparent substrate 1), thereby realizing an organic EL display device exhibiting high light emission efficiency.

To be more specific, the light emitting efficiency of the organic EL display device is greatly affected by not only the light-extraction efficiency of the organic EL element 18 itself but also the other factors. For example, even if light can be extracted from the organic EL element itself with high efficiency, it is impossible to improve sufficiently the light-emitting efficiency of the organic EL display device unless light can be extracted with high efficiency from the light-transmitting insulating layer (transparent substrate 1) arranged on the front side of the organic EL element 18.

In other words, in order to improve sufficiently the light-emitting efficiency of the organic EL display device, it is necessary to suppress sufficiently the total internal reflection of the light incident on the light-transmitting insulating layer at the interface between the light-transmitting insulating layer and the outside (typically, the air). To be more specific, it is important to suppress the total internal reflection of the light incident from the first waveguide layer (extending from the organic material layer 16 to the front side electrode 13) into the second waveguide layer (i.e., the light-transmitting insulating layer) at the interface of the light-emitting surface of the second waveguide layer.

According to the investigation conducted by the present inventors, it has been clarified that, in order to suppress sufficiently the total internal reflection of the light incident on the light-transmitting insulating layer at the interface between the light-transmitting insulating layer and the outer atmosphere, it is necessary for the light that is to be incident on the light-transmitting insulating layer to fall within a range of the critical angle between the light-transmitting insulating layer and the outer atmosphere and to have a very high directivity. To be more specific, in order to realize a sufficient viewing angle, it is necessary to enhance the directivity of the light until it is necessary to use a light scattering layer.

Under the circumstances, the three-dimensional diffraction element 10 having a cross-sectional structure of a specified dielectric constant modulation represented by formula (1) given previously is arranged in the first embodiment at the interface between the first waveguide layer and the second waveguide layer, i.e., between the front side electrode 13 and the passivation film 9. As a result, the light incident on the light-transmitting insulating layer is diffracted by the three-dimensional diffraction element 10, thereby achieving the light incidence having a high preference for the light-transmitting insulating layer so as to improve the light-extraction efficiency. It follows that it is possible to realize an organic EL display device having high light emission efficiency.

Particularly, it is possible to obtain an organic EL display device having a further improved light emission efficiency by setting appropriately the depth h of the periodic structure of the refractive index shown in FIG. 3 directed to the three-dimensional diffraction element 10. Specifically, the depth h noted above is set at a value smaller than 125 nm (i.e., h<125 nm) in view of the formula of h=λ/2(n1−n2), where λ denotes the wavelength of the light emitted from the light-emitting layer 16a, n1 denotes the refractive index of the first layer 11 and n2 denotes the refractive index of the second layer 12.

As a matter of fact, it was possible to obtain an organic EL display device having a further improved light emission efficiency, when the three-dimensional diffraction element was constructed to include the first layer formed of SiN having a refractive index of 2.0 and the second layer formed of a resin having a refractive index of 1.4, and was shaped to have a rectangular cross-sectional shape adapted for increasing the intensity of the primary light and having 100 nm of the depth h of the periodic structure and 350 nm of the period Λ.

Also, according to the first embodiment, the directivity of the light emitted from the transparent substrate 1 is markedly increased as described above. The directivity of the light can be changed freely by the light scattering layer 19 in accordance with, for example, the use of the organic EL display device. For example, where the organic EL display device is used in portable equipment such as a portable telephone, a wide viewing angle is not required in the organic EL display device. What is required is a bright display or low power consumption. Therefore, in such a use, it is possible to use the light scattering layer 19 having a low light scattering performance. Also, where the organic EL display device is utilized as a display device of stationary equipment, a wide viewing angle is required in the organic EL display device. Therefore, in such a use, it is possible to use the light scattering layer 19 having high light scattering performance.

As described above, it is possible to utilize the extracted light more effectively so as to improve the light emission efficiency by taking out the light having a directivity in a certain direction and by controlling the directivity by the light scattering layer 19 in accordance with the use of the extracted light.

Incidentally, the light scattering layer 19 is utilized as the diffusion means in the first embodiment described above. However, it is also possible to employ another construction as the diffusion means. For example, it is possible to roughen the surface of the transparent substrate so as to utilize the roughened surface as the light scattering surface. Further, it is also possible to use a diffusion means that does not utilize the light scattering. For example, it is possible for the diffusion means to be formed of a lens array prepared by arranging a plurality of diffusion lenses in place of the light scattering layer.

### Second Embodiment

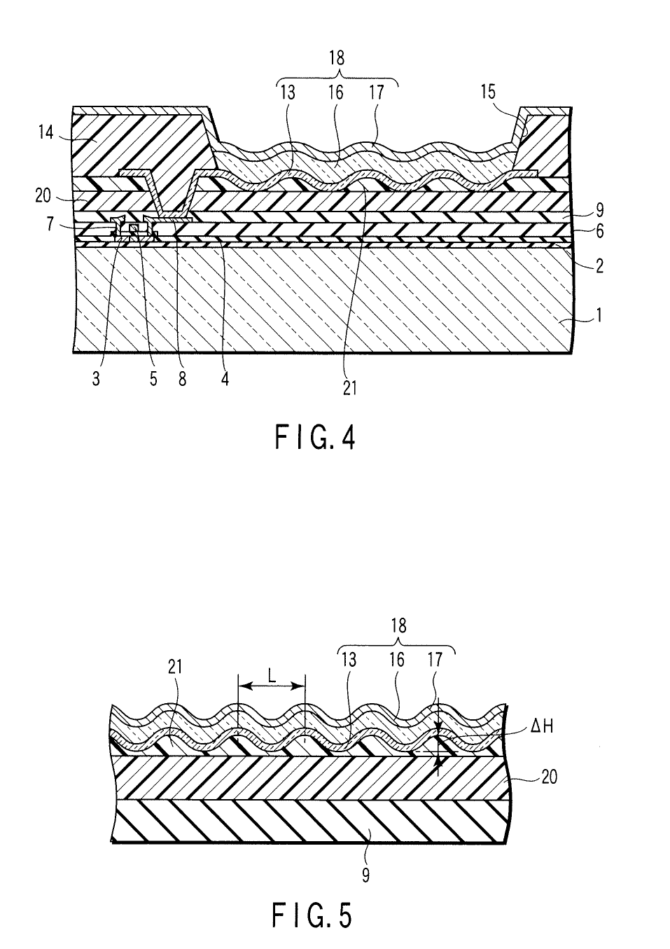

FIG. 4 is a cross-sectional view showing the construction of an organic EL display device of the lower surface light emission type employing an active matrix type driving system according to a second embodiment, and FIG. 5 is a cross-sectional view showing the construction in the gist portion of the organic EL display device shown in FIG. 4.

Incidentally, the organic EL display device is depicted in FIG. 4 to permit the display surface, i.e., the front side, to face downward, with the back side facing upward. It should also be noted that, the members shown in FIG. 4, which are equal to those shown in FIG. 1, are denoted by the same reference numerals so as to avoid the overlapping description.

In the organic EL display device shown in FIG. 4, a flattening layer 20 consisting of, for example, a resin material is formed on the passivation film 9. A waved layer 21 consisting of, for example, a resin material is formed on the flattening layer 20. Further, the organic EL element 18 comprising the front side electrode 13, the organic material layer 16 including the light-emitting layer, and the back side electrode 17 is formed on the waved layer 21. The organic EL element 18 is bent to form a waved pattern that is waved at a prescribed period, and the waved pattern is transferred onto the surface of the waved layer 21. As shown in FIG. 5, it is desirable for the waved organic EL element 18 to have a period L between the adjacent crests or between the adjacent valleys of the wave of 5 to 8 μm and to have a difference ΔH in height between the crest and the valley of 1 to 2 μm.

Incidentally, the waved layer 21 can be formed by, for example, applying a photo etching process to a photosensitive resin layer so as to form an irregular surface, followed by applying a heat treatment to the irregular surface so as to generate the reflow of the surface.

As described above, according to the second embodiment, the organic EL element comprising the front side electrode 13, the organic material layer 16 including a light-emitting layer and the back side electrode 17 is waved so as to realize an organic EL display device exhibiting high light emission efficiency.

To be more specific, the light-emitting efficiency of the organic EL display device is markedly affected by not only the light-extraction efficiency of the organic EL element 18 itself but also other factors. Even if the light can be extracted at high efficiency from the organic EL element 18 itself, it is impossible to enhance sufficiently the light emission efficiency of the organic EL display device unless light can be extracted at high efficiency from the light-transmitting insulating layer (transparent substrate 1) arranged on the front side of the organic EL element 18.

In other words, in order to enhance sufficiently the light emission efficiency of the organic EL display device, it is necessary to suppress sufficiently the total internal reflection of the light incident on the light-transmitting insulating layer at the interface between the light-transmitting insulating layer and the outside (typically, the outer air). In short, it is important to suppress the total internal reflection of the light incident from the first waveguide layer (organic material layer 16 and the front side electrode 13) onto the second waveguide layer (light-transmitting insulating layer forming the transparent substrate 1) at the interface of the light-emitting plane of the second waveguide layer.

According to the investigation conducted by the present inventors, it has been clarified that, in order to suppress sufficiently the total internal reflection of the light incident on the light-transmitting insulating layer at the interface between the light-transmitting insulating layer and the outer atmosphere, it is necessary for the light that is to be incident on the light-transmitting insulating layer to fall within a range of the critical angle between the light-transmitting insulating layer and the outer atmosphere and to have a very high directivity. To be more specific, in order to realize a sufficient viewing angle, it is necessary to enhance the directivity of the light until it is necessary to use a light scattering layer.

Such being the situation, the organic EL element 18 itself including the first waveguide layer is waved in the second embodiment of the present invention so as to permit the light radiated from the light-emitting layer included in the organic material layer 16 to be diffracted without being subjected to the total internal reflection at the interface of the second waveguide layer, i.e., the interface between the front side electrode 13 and the waved layer 21. The diffracted light is allowed to be incident below the waved layer 21, i.e., onto the light-transmitting insulating layer, thereby achieving the light incidence having a high preference for the light-transmitting insulating layer so as to improve the light-extraction efficiency. It follows that it is possible to realize an organic EL display device having high light emission efficiency.

Particularly, an organic EL display device having a further improved light emission efficiency can be obtained by setting the period L (i.e., the distance between the adjacent crests or between the adjacent valleys of the wave) at 5 to 8 μm and by setting the difference ΔH in height between the crest and the valley of the wave at 1 to 2 μm.

### Third Embodiment

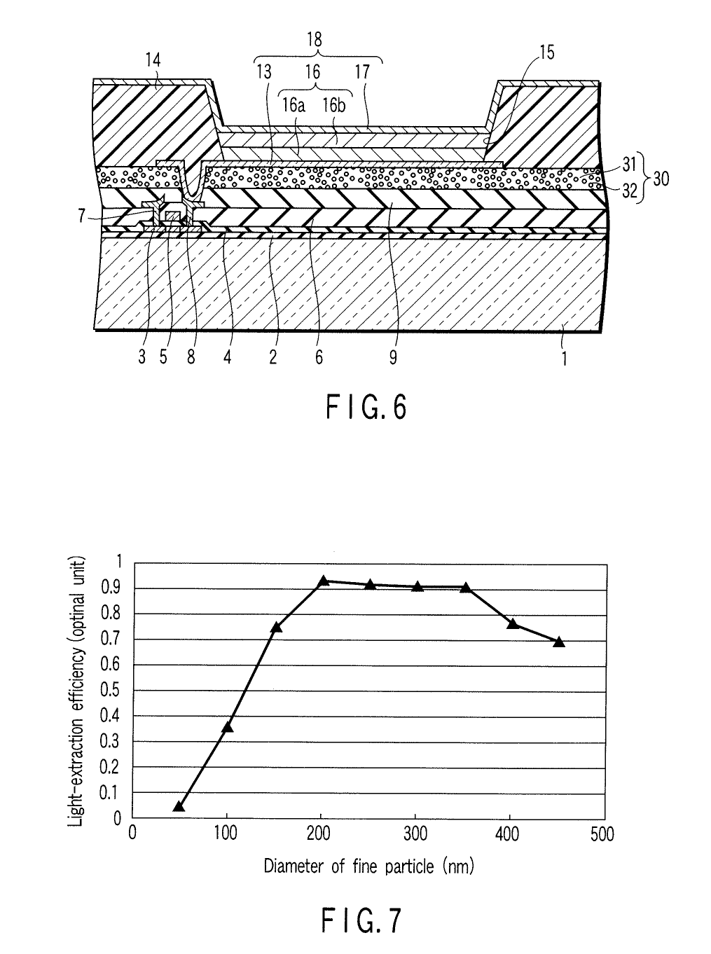

FIG. 6 is a cross-sectional view showing the construction of an organic EL display device of a lower surface light emission type employing the active matrix type driving system according to a third embodiment. Incidentally, the organic EL display device is depicted in FIG. 6 to permit the display surface, i.e., the front side, to face downward, with the back side facing upward. It should also be noted that the members shown in FIG. 6, which are equal to those shown in FIG. 1, are denoted by the same reference numerals so as to avoid the overlapping description.

In the organic EL display device shown in FIG. 6, a fine particle dispersion layer 30 acting as a light-extraction means is mounted on the passivation film 9. The fine particle dispersion layer 30 comprises a base material layer 31 (e.g., a resin material layer) and a large number of fine particles 32 having an average particle diameter of 100 to 350 nm and dispersed in the base material layer 31. It is possible for the fine particles to be formed of primary particles or secondary particles formed by agglomeration of the primary particles. The fine particles need not be dispersed regularly, and can be dispersed at random. The fine particle dispersion layer can be prepared by preparing a solution in which fine particles are dispersed in a resin material. The solution thus prepared is used in a coating operation by, for example, a spin coating method, followed by curing the coating by exposure to light or by heating so as to form the fine particle dispersion layer.

A through-hole communication with the drain electrode 8 is formed through each of the passivation film 9 and the fine particle dispersion layer 30. A plurality of light-transmitting front side electrodes 13 are formed apart from each other on the fine particle dispersion layer 30. In this example, the front side electrode 13 is used as an anode and is formed of a transparent conductive oxide such as indium tin oxide (ITO). The front side electrode 13 is electrically connected to the drain electrode 8 via the through-hole noted above. Further, a partition wall insulating film 14 is formed to cover the fine particle dispersion layer 30.

If the average particle diameter of the fine particles is smaller than 100 nm, it is difficult to extract efficiently the light emitted from the organic EL element described herein later. On the other hand, if the average particle diameter of the fine particles exceeds 350 nm, the coating capability is impaired in the step of forming a film, with the result that the flatness of the fine particle dispersion layer tends to be impaired.

In the fine particle dispersion layer 30, it is desirable to satisfy the relationship of n2>n1, where n1 denotes the refractive index of the organic resin material, and n2 denotes the refractive index of the fine particles. It is also desirable for the difference in the refractive index between n1 and n2 to fall within a range of 0.5 to 1.2. It is desirable for the resin material to be transparent. For example, a photosensitive resin such as PC403 (trademark, manufactured by JSR) or polyimide can be used as the resin material. These resin materials have a refractive index of about 1.5 to 1.6. Since the light-extraction effect is increased with increase in the refractive index, it is desirable for the fine particles to be formed of a material having a refractive index not smaller than 2.0. For example, it is desirable to use ZnO (refractive index of 2.0), ZrO₂ (refractive index of 2.0) or TiO₂ (refractive index of 2.7) for forming the fine particles.

It is desirable for the fine particle dispersion layer 30 to have a thickness of 500 nm to 1 μm, which is larger than the thickness of the dispersed fine particles. Also, it is desirable for the fine particles to be dispersed in the fine particle dispersion layer 30 at a deposition density of 10 to 50%.

As described above, the fine particle dispersion layer 30 is prepared by dispersing a large number of fine particles 32 having an average particle diameter of 100 to 350 nm in a base material layer 31, e.g., a resin material layer. The fine particle dispersion layer 30 thus prepared is arranged on the optical path guiding the light emitted from the light-emitting layer 16a included in the organic material layer 16 to reach the light-transmitting insulating layer (e.g., the transparent substrate 1). The particular construction makes it possible to realize an organic EL display device having high light emission efficiency.

The light subjected to the total internal reflection at the interface between the front side electrode 13 and the passivation film 9 is confined. It is difficult to extract the confined light to the outside. However, where the fine particle dispersion layer 30 prepared by dispersing a large number of fine particles 32 having an average particle diameter of 100 to 350 nm in a resin material layer 21 is arranged between the front side electrode 13 and the passivation film 9 as in the third embodiment of the present invention, the light confined by the total internal reflection is scattered by the fine particle dispersion layer 30 so as to improve the light-extraction efficiency. It follows that it is possible to realize an organic EL display device having high light emission efficiency.

Particularly, where the fine particle dispersion layer 30 satisfies the condition of n2>n1, where n1 denotes the refractive index of the organic resin material and n2 denotes the refractive index of the fine particles, and where the difference in the refractive index between the organic resin material and the fine particles is not smaller than 0.5, it is possible to obtain an organic EL display device having a further improved light emission efficiency.

As a matter of fact, a fine particle dispersion layer prepared by dispersing fine particles of TiO₂ fine particles (refractive index of 2.7) having a different average particle diameter of 50 to 450 nm in an acrylic photosensitive resin (refractive index of 1.54) was incorporated in the organic EL display device in the manner shown in FIG. 6 so as to measure the efficiency of extracting the light emitted from the light-emitting layer 16a included in the organic material layer 16. FIG. 7 is a graph showing the experimental data.

As apparent from FIG. 7, the light-extraction efficiency was increased when the average particle diameter of the TiO₂ fine particles dispersed in the fine particle dispersion layer was increased to exceed 100 nm, and the light-extraction efficiency was increased to reach the maximum level when the average particle diameter of the TiO₂ fine particles fell within a range of 200 to 350 nm. It should be noted, however, that, where the average particle diameter of the TiO₂ fine particles exceeds 350 nm, it was found difficult to form a flat fine particle dispersion layer. Also, when the average particle diameter of the TiO₂ fine particles was increased to 500 nm, it was substantially impossible to recognize the effect of improving the light-extraction efficiency.

### Fourth Embodiment

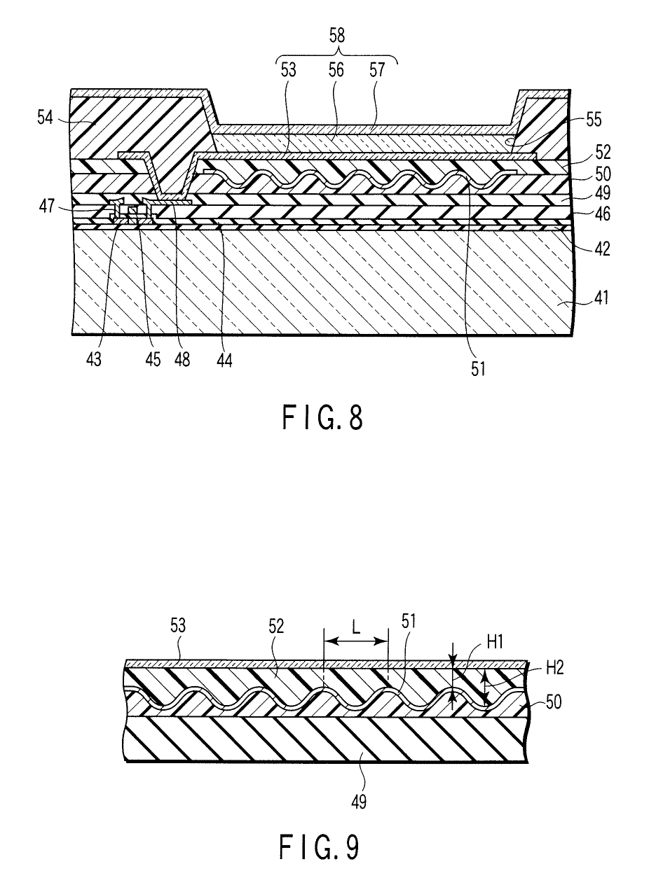

FIG. 8 is a cross-sectional view showing the construction of an organic EL display device of an upper surface light emission type employing the active matrix type driving system according to a fourth embodiment. Incidentally, the organic EL display device is depicted in FIG. 8 to permit the display surface, i.e., the front side, to face upward, with the back side facing downward.

In the organic EL display device shown in FIG. 8, a plurality of pixels are arranged to form a matrix on the insulating transparent substrate 41 such as a glass substrate. Each pixel comprises an element control circuit, an output switch, an organic EL element described herein later and a pixel switch, which are connected in series between a pair of power source terminals. The control terminal of the element control circuit is connected to a video signal line via the pixel switch so as to supply an electric current to the organic EL element via the output switch. The electric current noted above has a magnitude corresponding to the video signal supplied from a video signal line driving circuit via the video signal line and the pixel switch. Also, the control terminal of the pixel switch is connected to a scanning signal line such that the on/off operation of the scanning signal line is controlled by the scanning signal supplied from a scanning signal line driving circuit via the scanning signal line. Further, the control terminal of the output switch is connected to the scanning signal line such that the on/off operation of the scanning signal line is controlled by the scanning signal supplied from the scanning signal line driving circuit via the scanning signal line. Incidentally, it is possible to employ another construction in the pixel.

An undercoat layer 42 in which, for example, a SiNₓ layer and a SiOₓ layer are formed in the order mentioned in a manner to form a laminate structure, is formed on the substrate 41. Further, a semiconductor layer 43, a gate insulating film 44 and a gate electrode 45 are formed in the order mentioned on the undercoat layer 42 so as to form a top-gate-type thin-film transistor (TFT). The semiconductor layer 43 consists of poly-Si layer having, for example, a channel region, a source region and a drain region formed therein. The gate insulating film 44 is formed of, for example, tetraethyl ortho silicate (TEOS). Further, the gate electrode 5 is formed of, for example, MoW. In this example, the particular TFT is utilized in the pixel switch, the output switch, and the element control circuit. It should be noted that a scanning signal line (not shown) that is also formed in the process of forming the gate electrode 45 is formed on the gate insulating film 44.

An interlayer insulating film 46 consisting of a SiOₓ film formed by, for example, a plasma CVD method, is formed on the gate insulating film 44 including the gate electrode 45. Source/drain electrodes 47, 48, which are formed on the interlayer insulating layer 46, are connected, respectively, to the source region and the drain region of the TFT via contact holes extending through the interlayer insulating film 46. Each of the source/drain electrodes 47, 48 has a three layer structure of, for example, Mo/Al/Mo. Also, a video signal line (not shown) that can be formed in the process of forming the source/drain electrodes 47, 48 is formed on the interlayer insulating film 46. Further, a passivation film 49 consisting of, for example, SiNₓ is formed on the interlayer insulating film 46 including the source/drain electrodes 47, 48.

An insulating underlying layer 50 is formed on the passivation film 49. It is possible to use, for example, resin for forming the underlying layer 50.

That surface of the underlying layer 50 which faces the organic EL element described herein later includes a plurality of convex portions each having a cross section that is tapered forward. Incidentally, the expression “convex portion having a cross section that is tapered forward” implies a convex portion that is shaped such that the width is gradually decreased from the lower portion toward the upper portion in a cross section perpendicular to the film surface. In FIG. 8, the cross sections of these convex portions have curved lines such that the upper surface of the underlying layer 50 substantially forms a sine wave.

The convex portions of the underlying layer 50 are formed typically in a manner to form a periodic structure when the underlying layer 50 is viewed in a direction perpendicular to the film surface. For example, these convex portions are formed in a manner to form a two-dimensionally arranged structure such as a triangular lattice or a square lattice when the underlying layer 50 is viewed in a direction perpendicular to the film surface.

A reflective layer 51 is formed on the underlying layer 50. The upper surface of the reflective layer 51 is shaped to conform with the upper surface of the underlying layer 50. To be more specific, the upper surface of the reflective layer 51 includes a plurality of convex portions having a cross section that is tapered forward. In FIG. 8, each of these convex portions has a curved surface so as to cause the upper surface of the reflective layer 51 to be shaped to form substantially a sine wave. It is possible to use, for example, aluminum, an aluminum alloy such as aluminum-neodymium, silver or a silver alloy for forming the reflective layer 51.

A flattening layer 52 is formed in a manner to cover the underlying layer 50 and the reflective layer 51. The flattening layer 52 provides a flat underlying layer to the organic EL element 58. It is possible to use, for example, a transparent resin such as a silicone resin or an acrylic resin for forming the flattening layer 52.

The light-transmitting front side electrodes 53 are arranged apart from each other on the flattening layer 52. Each of the front side electrodes 53 is arranged to face the reflective layer 51. Also, each of the front side electrodes 53 is connected to the drain electrode 48 via the through-holes extending through the passivation film 49, the underlying layer 50 and the flattening layer 52.

The front side electrode 53 is used as an anode in this example. It is possible to use, for example, a transparent conductive oxide such as indium tin oxide (ITO) for forming the front side electrode 53.

The partition wall insulating layer 54 is arranged on the flattening layer 52. A through-hole 55 is formed in that portion of the partition wall insulating film 54 which corresponds to the front side electrode 53. The partition wall insulating layer 54, which is, for example, an organic insulating layer, can be formed by using a photolithography technology.

The organic material layer 56 including a light-emitting layer is arranged in contact with the front side electrode 53 exposed within the through-hole 55 formed in the partition wall insulating layer 54. The light-emitting layer is formed of a thin film containing a luminescent organic compound emitting a red, green or blue light. It is possible for the organic material layer 56 to further include another layer other than the light-emitting layer. For example, it is possible for the organic material layer 56 to further include a buffer layer performing the function of assisting the hole injection from the front side electrode 53 into the light-emitting layer. In addition, it is possible for the organic material layer 56 to further include a hole transfer layer, a blocking layer, an electron transfer layer or an electron injection layer.

The partition wall insulating layer 54 and the organic material layer 56 are covered with the light-transmitting back side electrode 57. In this example, the back side electrode 57 is used as a cathode mounted commonly for a plurality of pixels. The back side electrode 57 is electrically connected to an electrode wiring formed on the same layer of the video signal line through the passivation film 46, the underlying layer 50, the flattening layer 52 and the contact hole (not shown) formed in the partition wall insulating layer 54. These front side electrode 53, the organic material layer 56 and the back side electrode 57 collectively form each of the organic EL elements 58.

In the organic EL display device, the sealing with a can or with a protective film is performed in general for preventing the organic EL element 58 from being deteriorated by the contact with water or oxygen. Also, in the organic EL display device, a polarizing plate is arranged in general on the front side of the organic EL element 58.

It should be noted that the light emitted from the light-emitting layer is subjected partly to the total internal reflection at any of the interfaces on the front side of the organic EL display device. If the refractive index of each of the constituting factors of the display device is set appropriately, the light subjected to the total internal reflection is transmitted through the interface between the front side electrode 53 and the flattening layer 52. The particular light is called herein a totally reflected light.

Where the upper surface of the reflective film 51 forms a flat surface and is in parallel with the lower surface of the front side electrode 53, the angle of refraction at the time when the light emitted from the light-emitting layer is incident from the front side electrode 53 onto the flattening layer 52 is equal to the incident angle at the time when the light reflected from the reflective layer 51 is incident from the flattening layer 52 onto the front side electrode 53. It follows that all the totally reflected light noted above is confined within the inner space of the organic EL display device.

On the other hand, in the organic EL display device shown in FIG. 8, the upper surface of the reflective layer 51 includes a plurality of convex portions each having a cross section that is tapered forward. As a result, it is possible to permit the angle of refraction at the time when the light emitted from the light-emitting layer is incident from the front side electrode 53 onto the flattening layer 52 to differ from the incident angle at the time when the light reflected from the reflective layer 51 is incident from the flattening layer 52 onto the front side electrode 53. It follows that it is possible to extract at least partly the totally reflected light to the outside of the organic EL display device. In other words, it is possible to realize high light-extraction efficiency.

Where the running direction of the light is changed by inclining the reflecting surface of the reflective layer 51 relative to the lower surface of the front side electrode 53, the directivity of the light emitted from the organic EL display device is not rendered excessively high unlike the case of utilizing the diffraction. Particularly, in the organic EL display device shown in FIG. 8, the reflecting surface of the reflective layer 51 includes a curved plane, with the result that the reflective layer 51 performs the function of a light scattering layer. In other words, the organic EL display device is excellent in the viewing angle characteristics.

Further, the effects described above can also be obtained by diminishing the size and the interval of the convex portions formed on the upper surface of the reflective layer 51. The situation will now be described with reference to FIG. 9.

FIG. 9 is a cross-sectional view showing in a magnified fashion a part of the organic EL display device shown in FIG. 8.

In the construction shown in FIG. 9, the upper surface of the reflective layer 51 depicts a sine wave.

In this construction, the maximum diffraction effect can be obtained in the case where the product between the amplitude of the sine wave, i.e., 2(H2−H1)/2, which is equal to the height (H2−H1) of the convex portion, and the refractive index n of the flattening layer 52 is equal to ¼ of the wavelength λ of the light. For example, where the refractive index n is 1.5 and the wavelength λ of the light is 0.53 μm, the maximum diffraction effect can be obtained when the height H2−H1 is set at about 0.09 μm.

It is substantially impossible to obtain the diffraction effect, if the height H2−H1 is not smaller than 5 times as much as the value giving the maximum diffraction effect. In the example given above, it is substantially impossible to obtain the diffraction effect if the height H2−H1 is not smaller than about 0.5 μm. It follows that it is necessary to set the height H2−H1 at a value sufficiently smaller than about 0.5 μm in order to enhance the light-extraction effect by utilizing the diffraction effect.

Also, the effect of changing the running direction of the light that is produced by the diffraction is given by “sin⁻¹ (λ/L)” where L denotes the pitch of the convex portions, i.e., the wavelength of the sine wave formed by the upper surface of the reflective layer 51, and λ denotes the wavelength of the light. Where, for example, the wavelength λ of the light is 0.53 μm and the pitch L of the convex portions noted above is about 3 μm, the angle of diffraction is only about 10°.

On the other hand, where the light-extraction effect is enhanced by utilizing the inclination of the reflecting surface of the reflective layer 51, it suffices to set appropriately the angle of inclination of the reflecting surface, i.e., the ratio of the height H2−H1 to the pitch L. In other words, the values of the height H2−H1 and the pitch L are not particularly limited. It follows that the height H2−H1 and the pitch L can be increased to the extent that the reflective layer 51 can be formed at a low manufacturing cost. For example, it is possible to set the height H2−H1 of the amplitude at a value not smaller than 0.5 μm and the pitch L at a value not smaller than 3 μm.

Suppose, for example, the case where the reflective layer 51 is formed of an Al layer or an Al alloy layer having a thickness of 50 nm, the front side electrode 53 is formed of an ITO layer, and the back side electrode 57 is formed of a laminate structure consisting of a MgAg layer and an ITO layer. If the pitch L is set at 6 μm, and the minimum value H1 and the maximum value H2 of the distance in the thickness direction between the front side electrode 53 and the reflective layer 51 are set at 1.5 μm and 3.0 μm (height H2−H1=1.5 μm), respectively, it is possible to extract about 50% of the light, which is confined in the case where the reflective layer 51 is flat, to the front side of the organic EL element 58.

The ratio (H2−H1)/2L of the amplitude (H2−H1)/2 to the pitch L is set at, for example, about 0.1 to 0.5. In this case, it is possible to obtain a large effect of enhancing the light-extraction efficiency.

Also, the ratio H1/H2 of the minimum value H1 to the maximum value H2 of the distance in the thickness direction between the front side electrode 53 and the reflective layer 51 is set at a value smaller than, for example, 0.5. Where the ratio H1/H2 is large, it is possibly difficult for the flattening layer 52 to play the role of providing a flat underlying layer for the organic EL element 58.

As described above, it is possible to increase the amplitude (H2−H1)/2 and the pitch L in the organic EL display device shown in FIG. 8. Therefore, the method given below can be utilized for manufacturing the organic EL display device.

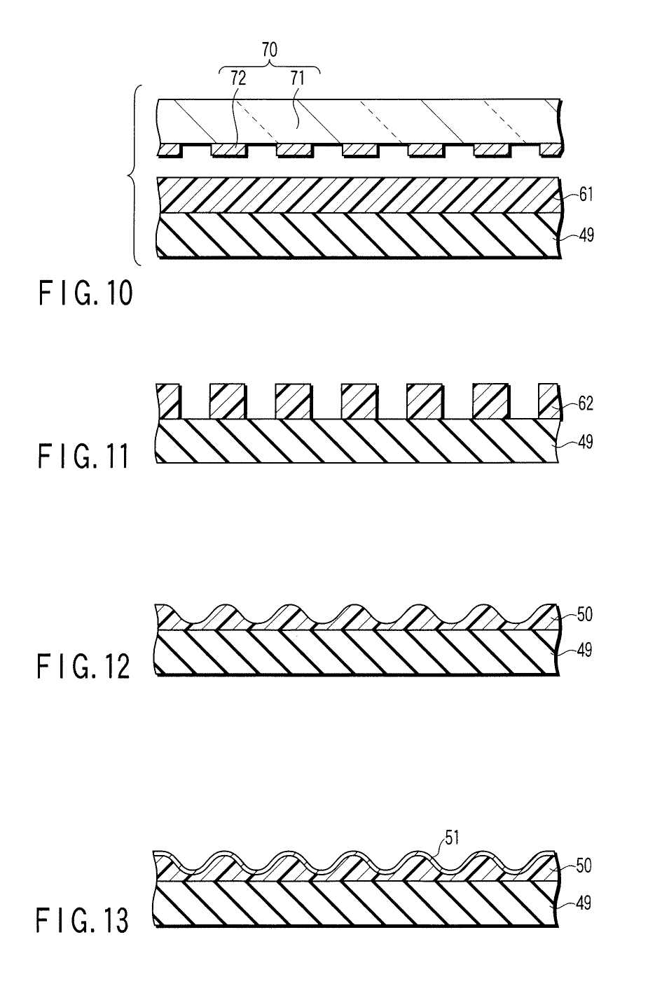

FIGS. 10 to 13 are cross-sectional views schematically exemplifying the method that can be utilized for forming the underlying layer 50 and the reflective layer 51 in the manufacturing process of the organic EL display device shown in FIG. 8.

In the first step, a photosensitive resin layer 61 is formed on the passivation film 49, as shown in FIG. 10. Then, the photosensitive resin layer 61 is irradiated with an energy beam such as an ultraviolet light via a photomask 70 prepared by forming a light shielding pattern 72 on the light-transmitting substrate 71.

In the next step, the photosensitive resin layer 61 is developed, thereby obtaining a resin pattern 62 consisting of a plurality of resin portions as shown in FIG. 11.

Then, the resin pattern 62 is heated so as to bring about reflow of the resin portion. If the heating temperature and the heating time of the resin pattern are set appropriately, it is possible to obtain the underlying layer 50 including a plurality of convex portions formed on the surface and each having a cross section that is tapered forward, as shown in FIG. 12.

After formation of the underlying layer 50, the reflective layer 51 is formed on the underlying layer 50 by, for example, a sputtering method, as shown in FIG. 13.

In the method described above, the resin pattern 62 shown in FIG. 11 is not used as an etching mask and, thus, differs from the ordinary method of forming a diffraction lattice. To be more specific, in the method described above, the underlying layer 50 having convex portions formed on the surface as shown in FIG. 12 was formed by utilizing the reflow of the resin pattern 62 shown in FIG. 11, followed by forming the reflective layer 51 on the underlying layer 50. It should also be noted that, since the amplitude (H2−H1)/2 and the pitch L can be increased as described previously, the change from the structure shown in FIG. 11 into the structure shown in FIG. 12 by utilizing the reflow of the resin pattern 62 can be controlled easily at high accuracy. It follows that the method described above makes it possible to form easily the reflective layer 51 having convex portions formed on the surface.

In the embodiment described above, a plurality of convex portions each having a cross section that is tapered forward, are formed on the surface of the reflective layer 51. Alternatively, it is possible to form a plurality of concave portions each having a cross section that is tapered forward on the surface of the reflective layer 51. Incidentally, the expression noted above, i.e., the expression “the concave portion having a cross section that is tapered forward” denotes a concave portion having a cross section in which the width is gradually decreased from the upper portion toward the lower portion. The particular reflective layer 51 can be obtained by carrying out the process described above with reference to FIG. 10 in a manner to obtain a lattice-shaped resin pattern 62 in place of the resin pattern 62 consisting of a plurality of resin portions shown in, for example, FIG. 11.

The present invention is not limited to the embodiments described above. The modifications achieved by those skilled in the art by utilizing other embodiments of the present invention are included in the technical scope of the present invention as far as the modifications include the main technical idea of the present invention.

What is claimed is:

1. An organic electroluminescent display device, comprising:
a light-transmitting insulating layer;
an organic electroluminescent element including a back side electrode arranged on the back side of the light transmitting insulating layer, a light-transmitting front side electrode interposed between the light-transmitting insulating layer and the back side electrode, and an organic material layer interposed between the front side electrode and the back side electrode and containing a light-emitting layer; and
a three-dimensional diffraction element of a two-layer structure arranged on the optical path guiding the light emitted from the light-emitting layer included in the organic material layer to reach the light-transmitting insulating layer;
wherein the three-dimensional diffraction element has a cross-sectional structure of a dielectric modulation represented by formula (1) given below and satisfying the relationship of Δ∈1>Δ∈q, where Δ∈1 denotes the amplitude in the case where q in formula (1) is equal to 1 (q=1), and Δ∈q denotes the amplitude of another degree in the case where q in formula (1) is larger than 1 (q>1):
$$Δɛ ( z ) = {\sum }_{q} Δ {ɛ}_{q} cos ( qKz ) \qquad ( 1 )$$
Where
Δ∈(z) denotes the change in the dielectric constant in the position z;
Δ∈q denotes the amplitude of the term of the q degree;
K is equal to 2π/Λ (where Λ denotes the period); and
z denotes the position in the horizontal direction.

2. The organic electroluminescent display device according to claim 1, which satisfies the condition of h<λ/2(n1−n2)
where h denotes the depth of the periodic structure of the refractive index of the three-dimensional diffraction element, λ denotes the wavelength of the light, n1 denotes the refractive index of the first layer material of the diffraction lattice, and n2 denotes the refractive index of the second layer material of the diffraction lattice.

3. An organic electroluminescent display device, comprising:
a light-transmitting insulating layer; and
an organic electroluminescent element including a back side electrode mounted to the back side of the light-transmitting insulating layer, a light-transmitting front side electrode interposed between the light-transmitting insulating layer and the back side electrode, and an organic material layer interposed between the front side electrode and the back side electrode and containing a light-emitting layer;
wherein the organic electroluminescent element is bent at a desired period to form a waved configuration.

4. The organic electroluminescent element according to claim 3, wherein the bent organic electroluminescent element has a period of 5 to 8 μm and a difference in height ΔH between the crest and valley of the waved organic electroluminescent element is 1 to 2 μm.

5. An organic electroluminescent display device, comprising:
a light-transmitting insulating layer;
an organic electroluminescent element including a back side electrode mounted to the back side of the light-transmitting insulating layer, a light-transmitting front side electrode interposed between the light-transmitting insulating layer and the back side electrode, and an organic material layer interposed between the front side electrode and the back side electrode and containing a light-emitting layer; and
a fine particle dispersion layer arranged on the optical path guiding the light emitted from the light-emitting layer included in the organic material layer to reach the light-transmitting insulating layer;
wherein the fine particle dispersion layer comprises a base material and a large number of fine particles dispersed in the base material and differing from the base material in the refractive index.

6. The organic electroluminescent display device according to claim 5, wherein the fine particles have an average particle diameter of 100 to 350 nm and also have a refractive index higher than that of the base material.

7. The organic electroluminescent display device according to claim 5 or 6, wherein the base material is formed of a photosensitive resin.

8. An organic electroluminescent display device, comprising:
an organic electroluminescent element including a light-transmitting back side electrode, a light-transmitting front side electrode arranged to face the back side electrode, and an organic material layer interposed between the back side electrode and the front side electrode and containing a light-emitting layer;
a reflective layer arranged to face the front side electrode; and
a light-transmitting flattening layer interposed between the reflective layer and the organic electroluminescent element;
wherein those surfaces of the reflective layer which are positioned to face the organic electroluminescent element are arranged at a prescribed pitch, each of the reflective layer and the organic electroluminescent element includes a plurality of convex portions and concave portions, each of the height of the convex portion and the depth of the concave portion being not smaller than 0.5 μm, the pitch being not smaller than 3 μm, and, when one cross section of the reflective layer is viewed, those surfaces of the reflective layer which are positioned to face the organic electroluminescent element depict a substantially sinusoidal waveform.

9. The organic electroluminescent display device according to claim 8, wherein the ratio H1/H2 of the minimum value H1 to the maximum value H2 of the distance in the thickness direction between the back side electrode and the reflective layer is smaller than 0.5.

10. The organic electroluminescent display device according to claim 8, wherein the material of the reflective layer is selected from the group consisting of aluminum, an aluminum alloy, silver and a silver alloy.

11. An organic electroluminescent display device, comprising:
an organic electroluminescent element including a light-transmitting back side electrode, a light-transmitting front side electrode positioned to face the back side electrode and an organic material layer interposed between the back side electrode and the front side electrode and including a light-emitting layer;
a reflective layer positioned to face the front side electrode; and
a light-transmitting flattening layer interposed between the reflective layer and the organic electroluminescent layer;
wherein the those surfaces of the reflective layer which are positioned to face the organic electroluminescent layer include a plurality of convex portions or concave portions each having a cross section that is tapered forward.
